(19) United States
(12) Patent Application Publication
(10) Pub. No.: US 2014/0034548 A1
(43) Pub. Date: Feb. 6, 2014

(54) WAFER CONTAINER

(71) Applicant: Texchem Advanced Products Incorporated Sdn Bhd, Bayan Lepas (MY)

(72) Inventors: JAMES D. PYLANT, TEMECULA, CA (US); ALAN L. WABER, WILDOMAR, CA (US); CHRISTOPHER R. MACK, BROOMFIELD, CO (US)

(73) Assignee: TEXCHEM ADVANCED PRODUCTS INCORPORATED SDN BHD, Bayan Lepas (MY)

(21) Appl. No.: 14/054,336

(22) Filed: Oct. 15, 2013

Related U.S. Application Data
(63) Continuation-in-part of application No. 12/749,448, filed on Mar. 29, 2010, now Pat. No. 8,556,079.
Application No. 12/749,448 is a continuation-in-part of application No. 12/606,921, filed on Oct. 27, 2009.
Application No. 12/749,448 is a continuation-in-part of application No. 12/548,368, filed on Aug. 26, 2009, now Pat. No. 8,109,390.
Application No. 12/606,921 is a continuation-in-part of application No. 12/548,368, filed on Aug. 26, 2009, now Pat. No. 8,109,390.

(51) Int. Cl. H01L 21/673

(52) U.S. Cl. CPC H01L 21/67353; H01L 21/67373
USPC 206/710

(57) ABSTRACT

Improvements in a semiconductor wafer container for reducing movement of semiconductor wafers within a wafer carrier using flexible wall segments, panels or flexible inserts in the base member's main inner containment diameter. These walls allow a vertical containment surface to move and capture the entire stack of wafers rather than a few wafers. The surface that contacts the wafers moves uniformly inward. The wafer stack is secured by reducing or eliminating the gap between the wafer container and the wafer stack. Further improvements include the addition of a ramped engagement surfaces in the top and/or bottom cover that provides mechanical advantage for easier assembly of the top and bottom cover. This design also allows for automated loading and unloading of the wafer stack because once the top cover is removed, the flexible walls spring back outward. Thus providing a small gap in which to freely remove the wafers.

### RELATED APPLICATIONS

The present application is 1) a continuation-in-part of Ser. No. 12/749,448, filed on Mar. 29, 2010, now U.S. Pat. No. 8,556,079, issued Oct. 15, 2013; and 2) a continuation-in-part of Ser. No. 12/606,921, filed on Oct. 27, 2009; both of are continuations-in-part applications of Ser. No. 12/548,368, filed on Aug. 26, 2009, now U.S. Pat. No. 8,109,390, issued Feb. 7, 2012. The entire disclosure of all of the above applications is incorporated by reference herein, including all the drawings.

### FIELD OF THE INVENTION

This invention relates to improvements in a container for the transportation of semiconductor wafers. More particularly, the present wafer container includes improvements in clamping sidewalls that prevent movement to the wafers, improved cover design to minimize rotation, a simplified top cover orientation mechanism and an improved bottom holding mechanism for automation.

### BACKGROUND OF THE DISCLOSURE

In the processing of semiconductor wafers, they typically must be transported either between processes or to other facilities. The semiconductor wafers are fragile and damage to the surface of the wafers can make the wafer useless for the intended purpose. Because of the high potential for damage to the wafer the semiconductors must be packaged and transported to minimize harm. In transportation, multiple semiconductor wafers are stacked into a transportation container. There have been a number of containment products and patents, which have been sold and patented to minimize damage to these silicon wafers. Exemplary examples of patents covering these products are disclosed herein.

U.S. Patent Publication Number US2006/0042998 that was published on Mar. 2, 2006 to Cliffton C. Haggard et al., discloses using a cushion insert that is placed on top of the wafers. When the lid is closed on top of the cushion insert, the support portions push on the inside of the lid. This causes the cushioning member to conform around the wafer at contact points. While this reference minimizes movement of the wafers, the wafers are stored vertically and the cushioning is applied on the closing side of the enclosure. The closing of the carrier pushes down on the cushion instead of sliding on the cushion. Further, the cushion is not integrated with the enclosure and exists as a separate component.

U.S. Pat. No. 7,100,772 issued Sep. 5, 2006 to John Burns et al., discloses a containment device for retaining semiconductor wafers with several methods of pushing on the sides of a semiconductor wafer. In all of the embodiments, one half of the housing interacts with an arm located in the second half of the housing to press on the sides of the semiconductor wafer. In one embodiment, spring loaded pistons push on branch members. In another embodiment, an arm on a living hinge is pushed to make contact with the wafer. While this patent discloses a wafer carrier that reduces movement of the wafers, the wafers are stored vertically and the cushioning is applied on the closing side of the enclosure. The closing of the carrier pushes down on the cushion instead of sliding on the cushion. This patent uses multiple arms, one for each wafer. The top housing pushed down on the cushion instead of sliding on the arms to provide the cushion.

U.S. Pat. No. 6,988,620 issued Jan. 24, 2006 to Clifton C. Haggard et al., discloses a wafer container having a top housing with sidewall tab portions that have a chamfered edge that pushes against a corresponding chamfered edge in the bottom housing to push extensions against the wafers. In this patent the hinge bends from the bottom housing and can bow whereby making contact with some but not all of the wafers. The hinge does not swing from the sidewall of the wafer carrier and the contact point on the wafers is not distal from the hinge to evenly apply the force to the wafers.

U.S. Pat. No. 5,402,890 issued Apr. 4, 1995 to Toshitsugu Yajima et al., discloses a box container with a flexible liner box member that is placed between the top and bottom housings. There are wedge like ribs that slide on the inside sidewalls that push the liner box member against the sheet bodies placed within the enclosure. The interaction of closing the housing causes deformation of one part that makes contact with all of the sheet bodies within the housing. This patent requires a separate insert to provide the cushioning and the cushion is not integrated or hinged from either housing.

U.S. Pat. No. 5,024,329 issued on Jun. 18, 1991 to Peter Grohrock discloses a wafer shipper that uses a hinged movable sidewall. This sidewall has multiple living hinges that push a wafer securing means against the wafers when the bottom housing is secured into the top housing. The interaction of closing the housing causes deformation of one part that makes contact with all of the wafers within the housing. In this patent the wafers are stored vertically. This cushion pushes from only one side and pushes the wafers against an outside wall where they are susceptible to damage. The top housing pushes down on the cushion instead of sliding on the cushion.

U.S. Pat. No. 6,193,068 issued Feb. 27, 2001 to Lee Lewis et al., and U.S. Pat. No. 6,341,695 issued Jan. 29, 2002 to Lee Lewis et al., discloses a containment device for retaining semiconductor wafers. This patent discloses two concentric walls on the top and bottom housings that nest to protect the semiconductor wafers. Double walls were designed to protect the wafers from the direct transmission of forces that may contact the outer wall. While the nesting walls provide protection from side impacts they do not provide flexibility to absorb and cushion a side impact or drop. The combination of an outer wall and a gap provide the protection. Damage may also occur if the force is such that the outer wall flexes enough to interfere with the inner wall, thereby damaging the wafers. That can cause the semiconductor wafers to shift and scratch.

U.S. Patent Publication Number US2009/0095650 that was published on Apr. 16, 2009 to James D. Pylant et al., discloses a wafer container with staggered wall structure. In this published application the design is limited by the amount overlap of the inner and outer walls by the design of its staggered walls. The walls were limited to 5% overlap, with 95 percent of the outer wall not located in adjoining angular sectors. This and other top cover rotation locating mechanisms use either an inner surface of a feature on the top cover or an exterior surface of a feature on the top cover to secure the top cover in place and prevent rotation.

U.S. Pat. No. 6,550,619 issued Apr. 22, 2003 to Gregory W. Bores et al., discloses a shock resistant variable load tolerant wafer shipper. This patent uses four inner tapered walls with a variable amount of cushions placed between the semiconductor wafers to pack and cushion the semiconductor wafer. While this patent allows for a variable amount of semiconductor wafers to be packed within the shipper the cushioning relies on the variable amount of cushions placed between the semiconductor wafers to reduce damage.

U.S. Pat. No. 7,040,487 issued on May 9, 2006 to Michael Zabka et al., discloses a protective shipper with a corrugated inner containment lip. The corrugated inner lip provides multiple surfaces for the edges if the semiconductor wafers to make contact with, but because the edges are corrugated the tangential walls of the corrugation limit the flexing of the inner lips.

Some semiconductor wafer containers use a rotation locking design where the locating mechanism with an exclusive inner surface or exterior surface do not securely capture the wall that they are adjacent to in both directions of rotation. These features stop rotation in only one direction. The features must rely on a sister feature to stop rotation in the opposite direction that is generally located farther away and allows for more manufacturing tolerance to build up since it is located at a greater distance. These deficiencies result in larger gaps between the plus and minus rotational limiting surfaces, thereby leading to more rotational movement.

There are a number of prior designs that use top cover orientation features with differing wall engagement angles or large latches as opposed to small slots. The new feature in this proposed wafer container allows improved orientation that is not found in the prior art.

Prior art designs have left the latch exposed to accidental contact that can open one or more of the latches that holds the two halves of the enclosure together. The designs all fail to address placing the latch in a well to prevent accidental opening during handling and shipping. In this application, the locking tab is placed within a recessed pocket where the latches are protected and enclosed in a powered well.

There are a number of different holding and clamping features in wafer shipping containers. All of these prior designs rely on multiple parts to create a clamping lip. These designs have several drawbacks including but not limited to the parts not being rigid with respect to the bottom assembly because they must be sonic welded, bonded or snapped together and that secondary parts or assembly operations are more expensive to produce.

The engagement of latches that secure the top and bottom housings together have a number of limitations. Specifically, prior art latches provide a raised straight slope ramp. The raise straight sloped surface is susceptible to damage. Moreover, the straight slope does not provide an ideal self gripping to engage between the top and bottom housings. The top cover orientation features use differing wall engagement angles or large latches as opposed to small slots as presented in this pending application.

What is needed is a semiconductor wafer container with improvements in side protection to the wafers, improved cover design to minimize rotation, a simplified top cover orientation mechanism and an improved bottom holding mechanism for automation. Also, what is needed is a semiconductor wafer container with improvements in internal movement, side and top protection to the wafers, the improved wafer carrier having movable side walls that push against opposing sides of the wafer to eliminate movement of the wafer within the carrier. This pending application satisfies these requirements with novel improvements in the identified areas.

### SUMMARY OF THE INVENTION

It is an object of the semiconductor wafer container to limit the amount of radial movement of the wafer within the container. Limiting radial movement is important because when shipping “bumped” wafers, that are stacked on spacer rings where the rings touch the periphery of the wafer, it will not shift radially into the areas containing the solder bumps. The improvements increase the wafer containment device's ability to protect semiconductor wafers and reduce radial wafer shift for both bumped and non-bumped wafers. This design can be used with or without spacer rings between the wafers in the vertical stack.

It is an object of the semiconductor wafer container to incorporate flexible wall segments. The flexible wall or wall segments moves radially inward to take up the excess space between the wafer and the main inner diameter of the container. The flexible walls reduce the movement of the wafers or can contain inserts that move with the walls to reduce the movement of the wafers. These wall segments create an interference fit between the top cover and panel or by use of a ramped engagement surfaces in either the Top Cover and/or the Bottom Member. The flexible wall segments can consist of individual components with flexible inserts, or can be integral to the base where they are molded as one part.

It is an object of the semiconductor wafer container to include flexible panels within a constraining wall. The flexible panel is contained within the main inner walls of the wafer container. The flexible wall segments can be simply a flexible portion of the wall or a distinct panel that reduces the radial gap between the wafer container and the wafer or wafer stack. This mechanism could also include the radial movement of resilient inserts imbedded into the side walls and are engaged by the top cover to move vertical features of the resilient insert radially inward.

It is another object of the semiconductor wafer container to include flexible inserts that are embedded onto or into the flexible wall. The insert is a flexible or resilient inserts, whether separate pieces or overmolded onto the walls, using a resilient materials. The wall may include holes or slots for insertion and retention of the insert.

It is still another object of the semiconductor wafer container to include ramped engagement surfaces. When the wall segments are pushed radially inward they are in a generally vertical direction. The use of ramped surfaces minimize the amount of force required to assemble the Top Cover and Bottom Member together when loaded with the wafer stack. The ramped surface is on the backside of the flexible wall or panel segment and has a corresponding ramp on the top cover, which engages the flexible wall ramp and drives the panel radially inward.

It is an object of the semiconductor wafer container that has an overlapping double wall. The wall structure comprises multiple outer walls and multiple inner walls. The overlapping double containment wall increases semiconductor wafer protection during impact or shipping. Each inner wall shares a minimal percentage of a common angular sector with each adjacent outer wall. The inner wall is generally very stiff and does not absorb and cushion the wafers if the container is dropped or subject to impact. On the bottom assembly, the inner walls and outer walls are positioned in an offset and overlapping configuration provides maximum protection to the semiconductor wafers.

It is an object of the semiconductor wafer container to improve alignment of the top cover with the base. The alignment system includes reference tabs that are received by the cover and a visual identifier for guiding an operator in the proper alignment of the two halves of the container. The top cover orientation features prevent improper installation of the top cover to the bottom member. The top cover orientation feature is incorporated into the top cover that mates with the features of the double locking location feature. This orientation feature prevents installation of the top cover in plus or minus 90 degree locations about the central axis.

It is an object of the semiconductor wafer container to provide an improved locking mechanism for securing the two halves of a wafer container together. The bottom half comprises a wall structure perpendicular to the base. The wall structure comprises segmented inner and outer walls, where each portion of the wall structure has a distinctive arc length. The arc length of each inner wall does not completely overlap with the arc length of any outer wall.

It is an object of the semiconductor wafer container to provide an improved engagement feature for the locking tabs. These improved tabs include a cover for a wafer container that engages to a base. The cover includes one or more notches, each having a ramp that easily receive latches from the base.

It is another object of the semiconductor wafer container to incorporate bi-directional rotation locking feature(s). These features improve orienting the top member on the bottom member that decreases the amount of top cover rotation and movement with respect to the bottom member. This feature creates a double locking location that securely locates and locks the top cover in place during top cover assembly. The bi-directional rotation locking feature is located on both sides of the perpendicular top cover surfaces of a single wall on both the interior and the exterior simultaneously. This improvement provides bi-directional locking of the captured surface, decreases the amount of top cover rotation and movement with respect to the bottom member, and increases the rigidity of the containment device when the members are assembled.

It is another object of the semiconductor wafer container to incorporate a protective latch well. The latch well is a recess that is incorporated into the top cover which protects the latch arm from being accidentally bumped or inadvertently opened. The tip of the latch is surrounded by a wall that protects the latch by lowering the tip of the latch below the planar surface of the Top Cover by at least 2 mm. This recess distance or greater is considered to be adequate to protect the latch from accidental opening.

It is still another object of the semiconductor wafer container to include an improved holding and clamping feature to allow for automated machinery to latch onto and hold the bottom member and secure it firmly to the machinery nesting locations. This mechanism is comprised of a single piece feature that is molded into the bottom member. The holding and clamping feature on the bottom member improves equipment interface where these containers are used. The feature is a holding mechanism to allow for automated machinery to latch onto and hold the bottom member and secure it firmly to the machinery nesting locations.

It is still another object of the semiconductor wafer container to include an improved curved latch recess for improved closure and retention of the containment device latches. In the improved latch and latch recess, the height of the latch is equal to or lower than the inner wall structure. This allows equipment to interface with the bottom member of the container without interference with the equipment and latch height. A curvature on the mating surface provides superior holding and self centering and gripping during handling and after impact. This recessed feature also protects the mating surface from damage when the top cover is disassembled from the bottom member. The latch recess and curved surface also provides increased latch retention and container integrity during impact or shipping. This includes a lowered latch equal to or less than the inner wall height.

Various objects, features, aspects, and advantages of the present invention will become more apparent from the following detailed description of preferred embodiments of the invention, along with the accompanying drawings in which like numerals represent like components.

### BRIEF DESCRIPTION OF THE DRAWINGS

FIG. 1 shows a perspective exploded view of an embodiment of the wafer container with a plurality of wafers disposed between the two wafer container halves.

FIG. 2 shows a perspective exploded view of an embodiment of the wafer container with a plurality of wafers disposed between the two wafer container halves.

FIG. 3 shows a top view of the bottom housing of the embodiment of FIG. 1 with the ribs and the flexible walls.

FIG. 4 shows a top view of the bottom housing of the embodiment of FIG. 2 with the ribs and the flexible walls.

FIG. 5 shows a perspective view of a rib of the embodiment of FIG. 1 with two flexible wall segments.

FIG. 6 shows a detailed perspective view of overlapping inner rib walls of the embodiment of FIG. 2.

FIG. 7 shows a perspective cut away view of the top housing of the embodiment of FIG. 1 showing the ramped engagement rib.

FIG. 8 shows a perspective cut away view of the bottom housing of the embodiment of FIG. 1 showing the flexible wall segments.

FIG. 9 shows a perspective cut away view of the flexible wall and the ramped engagement rib of the embodiment of FIG. 1.

FIG. 10 shows a top view of the bi-directional locking feature in the bottom housing.

FIG. 11 shows a perspective view of the bi-directional locking feature on the bottom housing.

FIG. 12 shows a perspective view of the bi-directional locking feature on the top housing.

FIG. 13 shows an inside plan view of the top housing showing the orientation features.

FIG. 14 shows inside plan view of the bottom housing showing the orientation features.

FIG. 15 shows a detail perspective view of the orientation key in the top housing.

FIG. 16 shows a detail perspective view without the orientation key in the top housing

FIG. 17 shows a detail perspective view of the clearance for the orientation key in the bottom housing.

FIG. 18 shows a detail perspective view of the interference for the orientation key in the bottom housing.

FIG. 19 shows a top perspective view of the bottom housing.

FIG. 20 shows a detailed perspective view of the hold down latch.

FIG. 21 shows a perspective cross section of the hold down latch.

FIG. 22 shows a perspective view of the top and bottom latch tab engaged.

FIG. 23 shows a side view of the bottom latch tab.

FIG. 24 shows a sectional view of the latch engaged between the top and bottom housings.

FIG. 25 shows a detailed view of the engaged between the top and bottom housings.

FIG. 26 shows a perspective view of the top and bottom housings in an open exploded view for reference of the internal components.

### DETAILED DESCRIPTION OF THE EMBODIMENTS

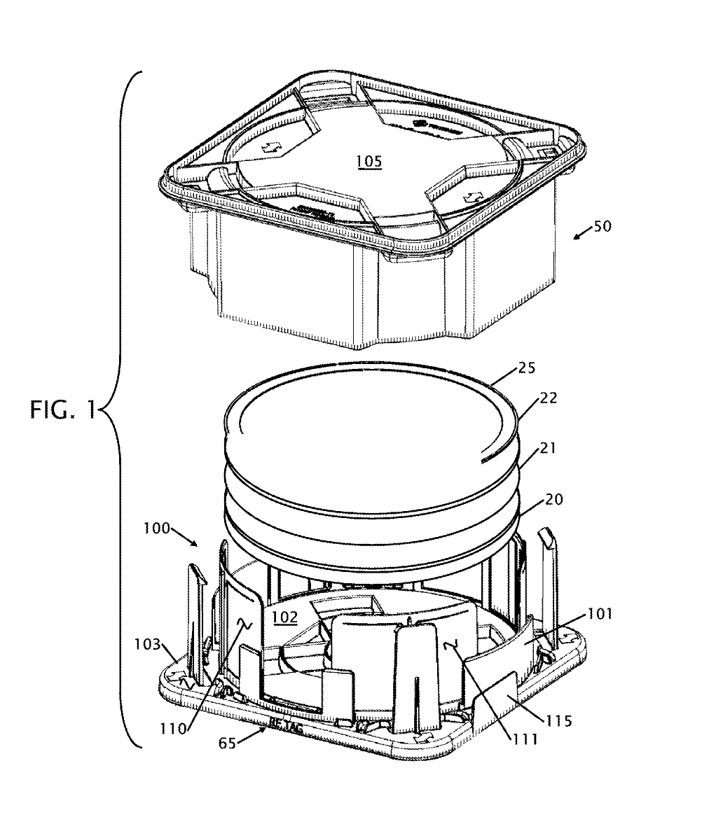

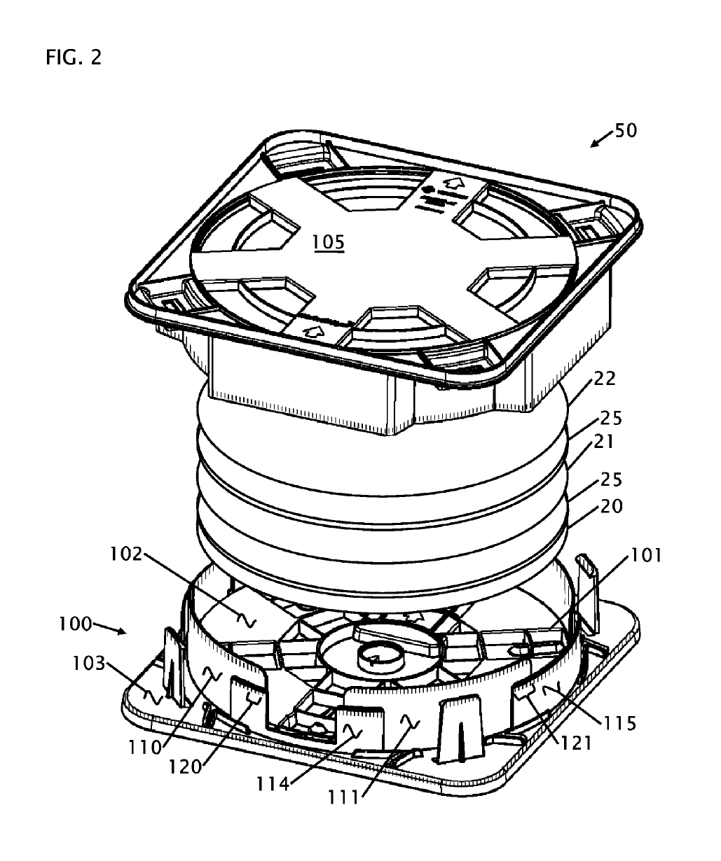

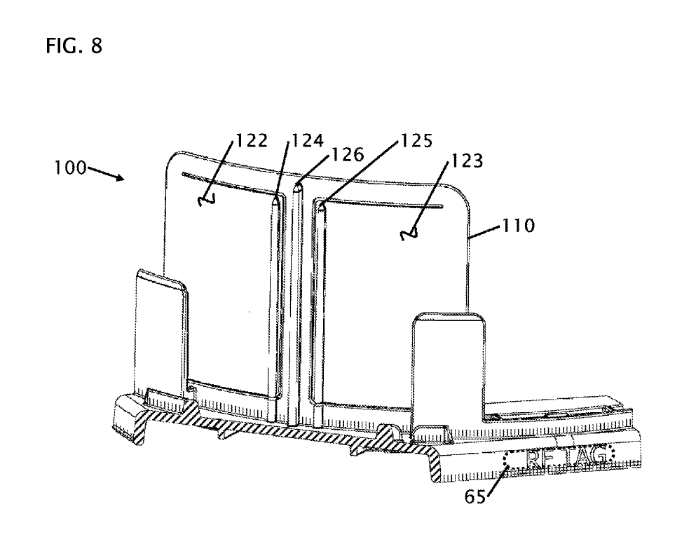

FIG. 1 and FIG. 2 show a perspective exploded view of the wafer container with a plurality of wafers disposed between the two wafer container clam shells. A plurality of semiconductor wafers 20, 21 and 22 are shown between the top 50 and bottom 100 housing with wafer separators or spacer rings 25. The top housing 50 has a planar top surface 105. The inside base surface 102 extends to the outside of the base surface 103 where the bottom housing has a ribbed pattern 101 that supports the bottom of the bottom most semiconductor wafer 20 and provides increased structural strength to the fairly plainer base surface 102 and 103. Both the top 50 and the bottom housings 100 have essentially planar rectangular or square bases. A plurality of inner rib walls 110 and 111that extend essentially perpendicular from the bottom housing 100 protect the semiconductor wafers 20-22 from shifting side damage. A rib 115 rises from the outer edge of the bottom housing to provide an area for labeling the wafer carrier. In addition to the label area, the wafer carrier has an area for a RF ID tag 65 (Also show in FIG. 8) to be inserted into the wafer carrier housing. This area is of the part is marked to identify the location of the RF ID to aid in scanning for the RF ID and eliminate the need to scan all the sides of the carrier to locate the RF ID.

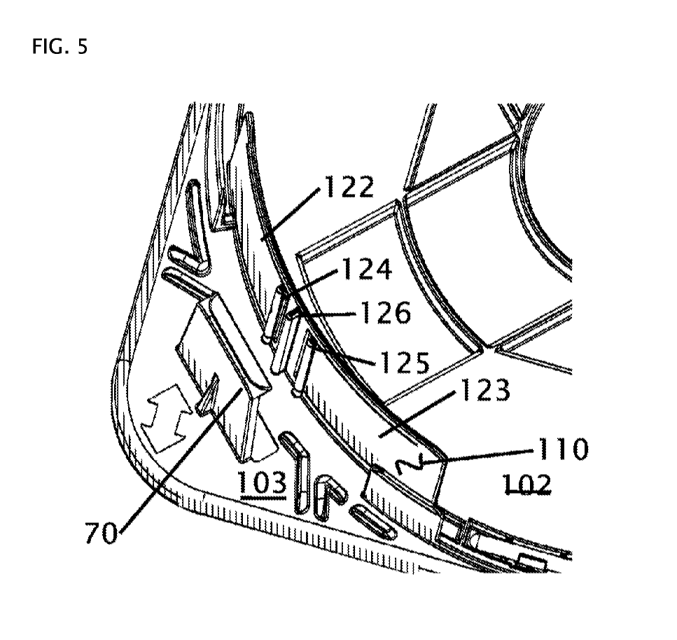

In FIG. 1, the inner rib walls are formed in the top housing provide flexible wall segments that are bent with when the top housing 50 is inserted onto the bottom housing 100. In this preferred embodiment, there are four vertical ribs and each vertical rib has two flexible walls. When the walls are flexed, the walls push radially inward or concentrically into the center of the wafer carrier to reduce the inside diameter of the central cavity and to clamp the wafers 20-22, wafer separators and or space rings 25. This is shown and described in more detail in the FIGS. 5, 7, 8, and 9 of this application.

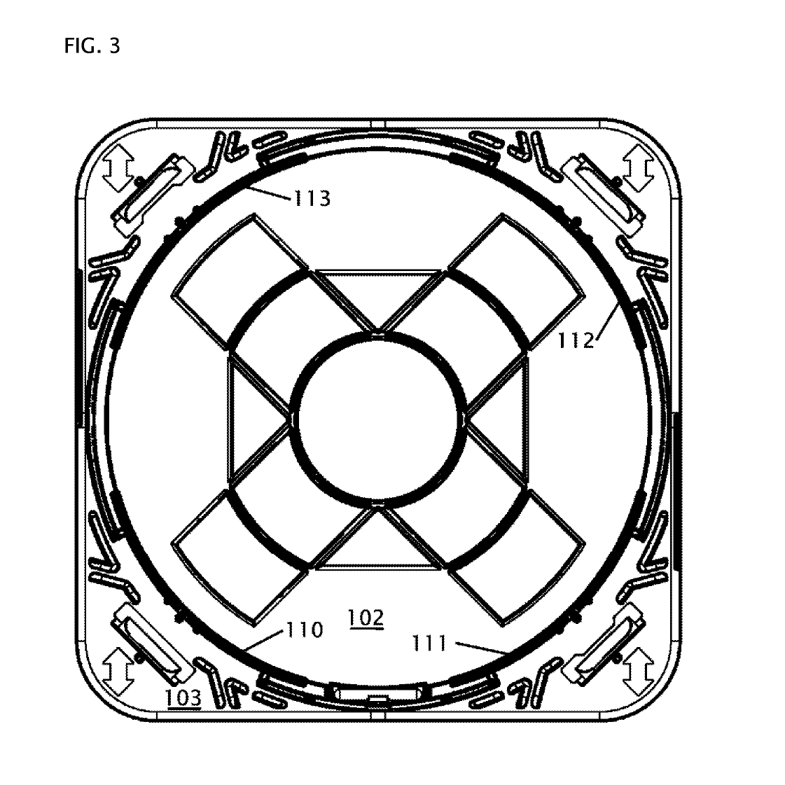

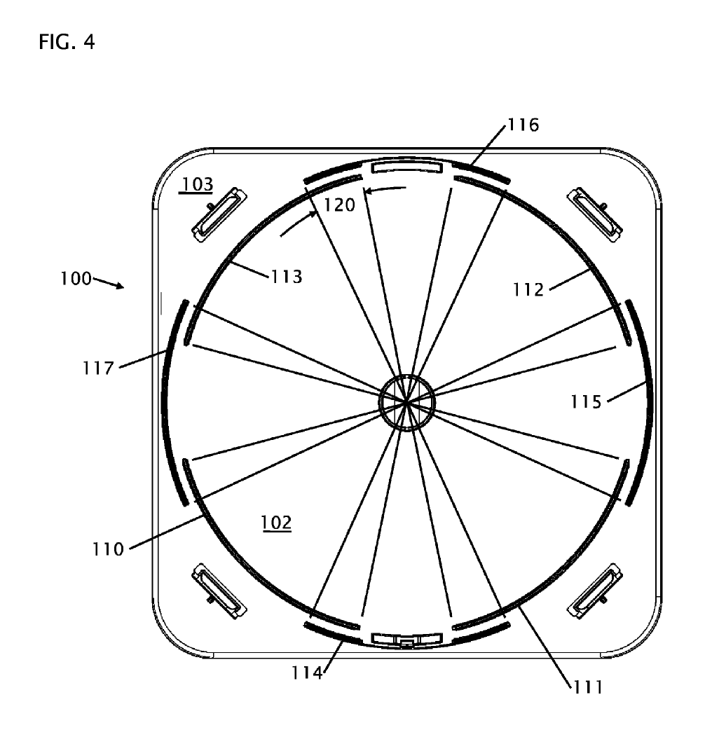

In FIG. 2, the inner rib walls 100 and 111 of the bottom housing 100 can flex to cushion side impact. They are formed in a segmented pattern in the bottom housing. The segmented ribs are shown and described in detail with FIG. 4. A second set of segmented outer ribs 112 and 113 exist outside of the inner rib walls 110 and 111. The rib walls exist in an overlapped 120 and 121 pattern to prevent debris from passing directly through the segmented ribs.

FIG. 3 shows a top view of the bottom housing with the ribs 110, 111, 112 and 113 all having two each flexible walls. The flexible wall is better shown with FIG. 5 that shows a perspective view of the rib with two flexible wall segments 122 and 123 on rib 110. Each flexible wall 122 and 123 has an associated boss, 124 and 125 respectively, which is pushed upon by a mating rib located in the top housing. As the top housing is pushed down onto the bottom housing, the bosses 124 and 125 are pushed towards the center of the wafer carrier.

The walls 122 and 123 will flex on the outer restrained portion of the rib 110 and bends into the center of the wafer carrier. Because there are eight flexible walls located around the wafer carrier the walls all will move inward in unison to push in on the wafer from all directions to clamp the wafer into the center of the wafer carrier. Moving all of the walls together further prevents damage to the wafers because they are not being pushed in only one direction and when the top housing is removed the wafer do not move back into a neutral position because the wafers are all being clamped and released from a plurality of outer directions.

FIG. 4 shows a top view of the bottom housing with the overlapping rib wall pattern. Note that some features, such as bottom ribs, have been deleted from the bottom surface 102 and 103 and the overlapping ribs have been moved slightly to improve clarity of the overlapping rib features being discussed herein.

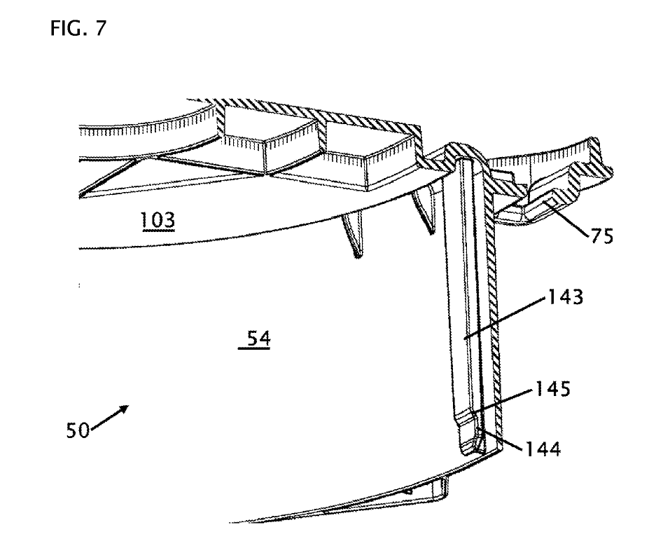

FIG. 5 shows one of the four centering ribs 126 between bosses 124 and 125. This centering rib is located to assist in alignment of the top and bottom wafer carrier housings and provides stiffness to the vertical wall or rib. The locking tab or latch 70 is also shown in FIG. 5. The features and functions of the locking tab or latch 70 is shown and described in more detail in the inventor's other patent application Ser. Nos. 12/548,368 and 12/606,921 incorporated by reference herein. This is one of four latches that lock into slots located in the top housing to secure the two halves of the wafer carrier together during transportation of the wafers. The bosses 124 and 125 are pushed with ramped ribs that are located on the top housing. The ramped engagement ribs are shown and described with FIG. 7.

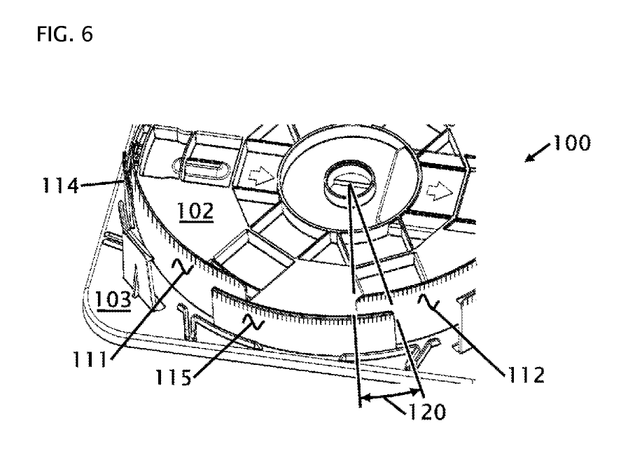

FIG. 6 shows a detailed perspective view of the overlapping inner rib walls. While in FIGS. 4 and 6 only one section of overlapping ribs is identified, the overlapping condition exists in eight places in the bottom housing 100. While the preferred embodiment shows four inner rib walls 110-113 and four outer rib walls 114-117 it is contemplated that a greater or lesser number of overlapping can be used. In FIGS. 4 and 6, the overlap 120 is labeled, and in the preferred embodiment the overlap angle is between 5 and 15 degrees, but prototypes have been made using an overlap angle 120 of 7.5 degrees. The ribs 110-117 are arc segments that extend perpendicular from the essentially planar base 102 and 103. These angles are variable based upon the height of the rib, the material, the thickness of the rib, the desired cushion and the distance between the inner and outer ribs. In general the distance between the inner and outer ribs is controlled based upon the annular rib in the top clam shell housing.

The overlapping double wall provides maximum protection from shock or impact to the exterior of the containment device by positioning the inner and outer wall in an offset and overlapping configuration as to increase the protection of the semiconductor wafers from direct transmission forces by increasing the amount of flex movement allowed by the outer wall. Increasing the flex tolerance of the outer wall increases the overall shock absorbing ability of the containment device. This design also allows for a greater percentage of “wrap” around the semiconductor wafer and therefore minimize lateral shift into the gaps between inner wall segments. Segmenting the inner wall makes it more flexible and thus able to absorb and cushion the wafers if the container is dropped or subject to impact.

As shown in FIGS. 2 and 6, the outer rib walls 114-117 need not be the same height as the inner rib 110-113 walls. In some cases, the lowered exterior wall allows for greater top cover deflection during impact before it touches the inner wall. The image in the figures show the exterior rib walls 114-117 at approximately ⅔rds the height of the inner rib walls 110-113 as shown in FIG. 2.

FIG. 7 shows a perspective cut away view of the top housing showing one of the eight ramped engagement rib. The top housing has been cut away to more clearly show rib 143 that extends from the outside rib wall 54. The outside rib wall 54 exists continuously around the wafer cavity to prevent contamination from entering into and or onto any stored semiconductor wafers that would be located within the wafer carrier. The rib 143 has a ramped or stepped wall section 144 that provides a start of engagement prior to pushing on the tapered area 145 of the bosses 124 and 125 on the lower housing as shown in FIG. 8. This figure also shows the notch 75 that engages with the locking tab 70 as shown in FIG. 5 that are described in more detail in the inventor's other patent application Ser. Nos. 12/548,368 and 12/606,921 incorporated by reference herein.

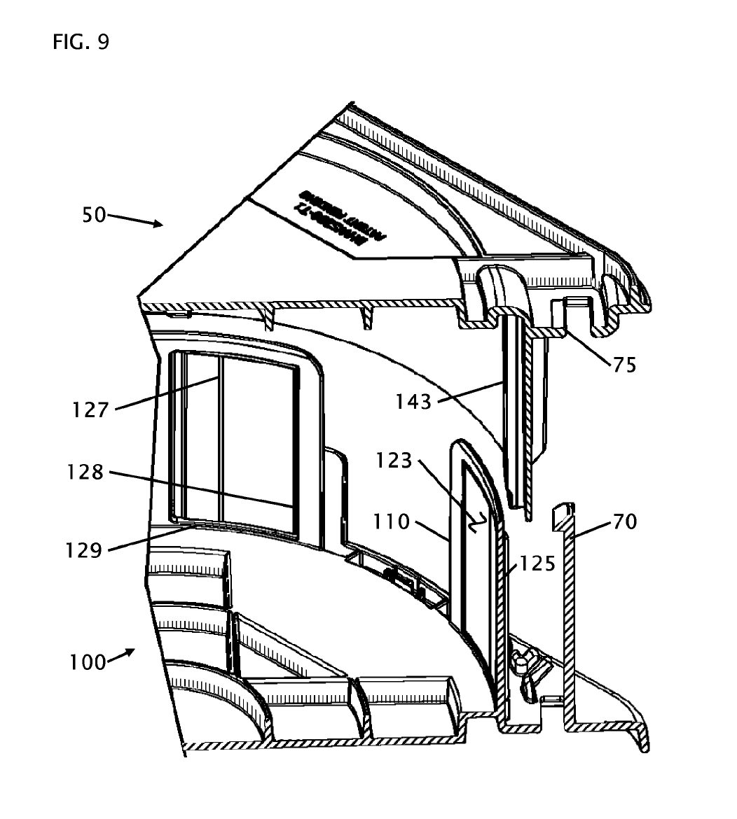

FIG. 8 shows a perspective cut away view of the bottom housing showing the flexible wall segments. In FIG. 8, the locking tab or latch 70 (shown in FIG. 5) has been removed to provide an unobstructed view of the flexible walls 122 and 123. The rib 143 (from FIG. 7) engages onto the bosses 124 and 125 to hinge the flexible walls 122 and 123 inward. A centering rib 126 is shown between the bosses 124 and 125. This centering rib passes between two ribs 143, located in top housing 50, to prevent the ribs 143 from pushing in an undesirable location on the bottom housing 100. Alignment is shown in more detail with FIG. 9.

FIG. 9 shows a perspective cut away view of the flexible wall 123 on rib 110 of the bottom housing 100 and the ramped engagement rib 143 on the top housing. The top housing 50 is pushed down onto the bottom housing 100 until the locking tab or latch 70 engages and locks into the notch 75 in the top housing 50. To separate the two housings the locking tab or latch 70 is pushed out of the notch 75 and the housings can be pulled apart. As the housings are pulled apart the engagement rib 143 slides off of the boss 125 such that flexible wall 123 springs back away thereby releasing the wafers. In this figure, an insert or pad 127 is shown on the inside of the flexible wall. The pad 127 can be an inserted, over molded or integrated into or from the wall. This pad 127 is preferably an elastomeric and provides an additional cushion to the wafer as well as increasing the coefficient of friction of the flexible wall to grip the silicon wafers, or spacers. It should be noted that the location of this cushion or pad 127 is not placed at the hinge end or directly behind where a boss 125 would exist. The location of the cushion or pad 127 is paced between these two locations to allow the flexible wall to bend at the point of contact with the wafer(s). Because the point of contact is between the hinge location and the boss location the flexible wall provides additional flexing to further cushion the wafers. The cushions, pads or flexible inserts 127 can be embedded onto or into the flexible wall. The insert is a flexible or resilient inserts, whether separate pieces or over molded onto the walls, using a resilient materials. The wall may include holes or slots for insertion and retention of the insert. In this figure, the living hinge area 128 is shown where the wall is thinned to allow for flexing. The living hinge is a hinge that is formed from the wall material where the wall material is unsupported on three sides. Pressure on the end of the free end of the hinge allows the wall to bend. The wall is thinned at location 128 to allows for easier flexing or hinging at a more localized area of the wall.

A radial support for the wafer ring 129 is also shown to support the lowermost wafer ring.

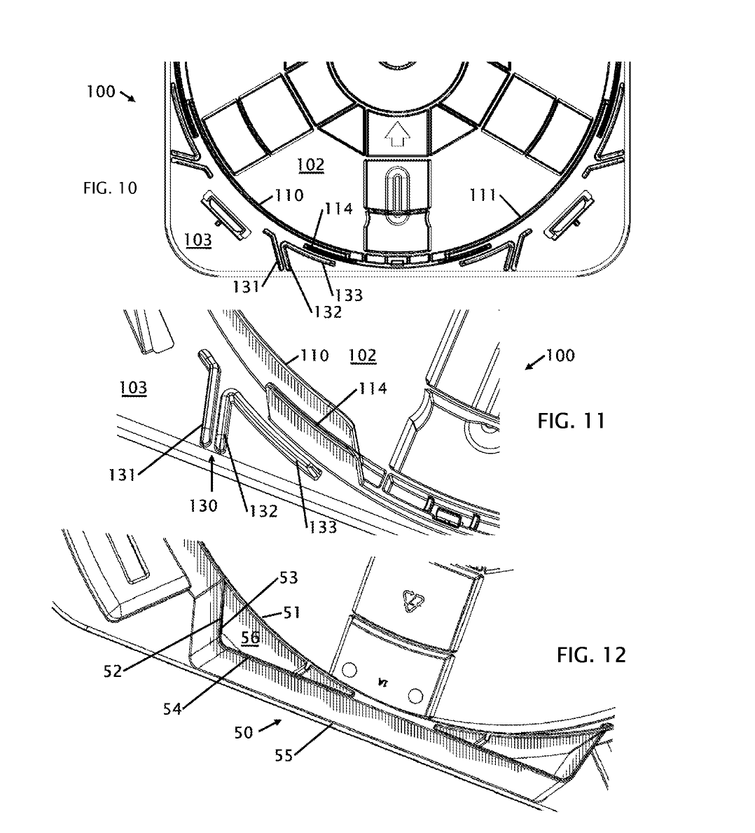

FIG. 10 shows a top view of the bi-directional locking feature in the bottom housing 100. FIG. 11 shows a perspective view of the bi-directional locking feature on the bottom housing 100. FIG. 12 shows a perspective view of the bi-directional locking feature on the top housing 50. Starting with FIG. 12 the circular rib 51 is shown extending from the planar base of the top housing 50. A “U” shaped rib extends from the circular rib 51 to the outer edge 55 of the top housing 50 and around to join back with the circular rib 51. This “U” shaped rib can exist in a variety of shapes to provide a key to ensure that it locks into only one of four possible orientations with the bottom housing 100. This “U” shaped rib that extends to the outer edge 55 has an inside face 53 and an outside face 52. Where the “U” shaped rib joins with the outer edge 55 there is an outside protection and support rib 54.

A pair of securing ribs consisting of an outer locking rib 131 and an inner locking rib 132 on the bottom housing 100 are configured to engage onto the opposing sides of the inside face 53 and an outside face 52 of the “U” shaped rib when the “U” shaped rib is engaged into the locking cavity 130. Circular lock rib 133 is configured to fit within cavity 56 on the top housing 50 along with the inner lock rib 132. When the rib defined by items 52/53 is engaged into the locking cavity 130 these features improve orienting, the top housing 50 on the bottom housing 100 that decreases the amount of top cover 50 rotation and movement with respect to the bottom member 100. This feature creates a double locking location that securely locates and locks the top cover 50 in place during top cover assembly. The bi-directional rotation locking further increases the rigidity of the containment device when the members are assembled. The “U” shaped and is shown in an approximate orthogonal relationship to three sides of the bottom housing 100. While only one location of the bi-directional lock is shown and described in detail, the feature exists on all four sides of the top and bottom housings.

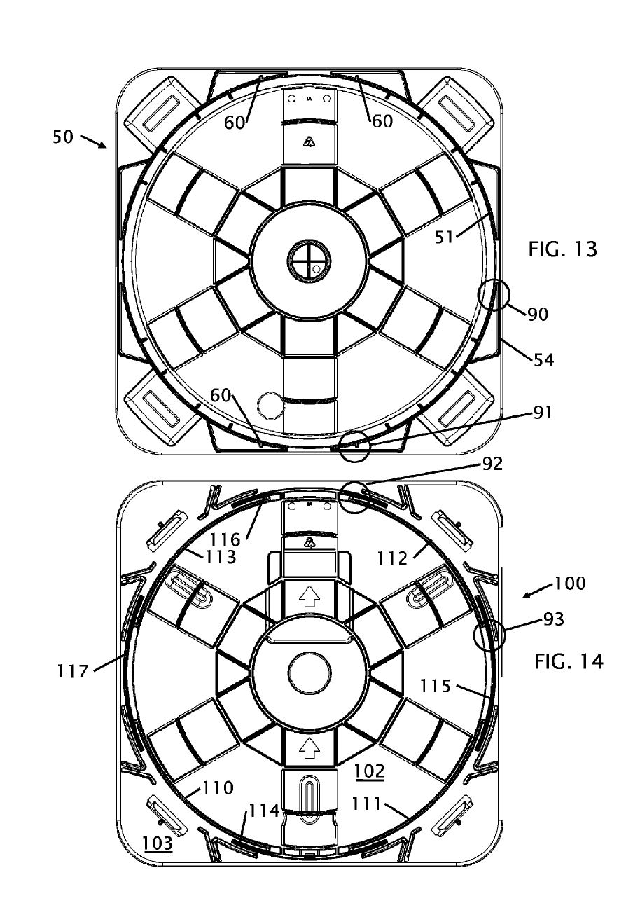

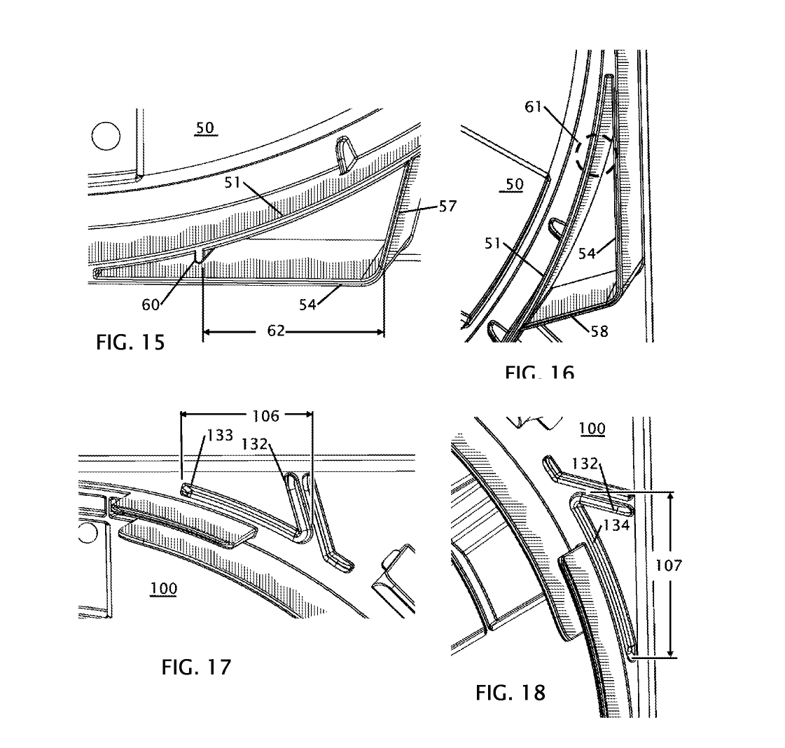

FIG. 13 shows an inside plan view of the top housing showing the orientation features and FIG. 14 shows inside plan view of the bottom housing showing the orientation features. FIG. 15 shows a detail perspective view of the orientation key in the top housing. FIG. 16 shows a detail perspective view without the orientation key in the top housing. FIG. 17 shows a detail perspective view of the clearance for the orientation key in the bottom housing. FIG. 18 shows a detail perspective view of the interference for the orientation key in the bottom housing. For perspective, the area's 90, 91, 92 and 93 are shown enlarged and in perspective in FIGS. 9, 10, 11 and 12 to show the orientation tab 60 and how in allows or blocks seating of the top and bottom housings 50 and 100.

In FIG. 15 the orientation rib 60 is shown extending essentially normal from the circular rib 51 at a particular distance 62 from the corner of the “U” shaped rib 54 and 57. In FIG. 16 the orientation rib is not present in area 61 in the corner of the “U” shaped rib 54 and 58. Now refer to FIGS. 17 and 18 to see where the orientation rib 60 would be blocked or bypassed by the details. In FIG. 17 the dimension 106 between the corner radius of curved lock rib 133 and the inner lock rib 132 is shorter than the distance 107 between the curved lock rib 134 and the inner lock rib 132 in FIG. 12. Upon placement of the top housing onto the bottom in an out of proper orientation arrangement the longer circular block rib 134 would interfere with the orientation rib 60. In the correct orientation the shorter circular lock rib 133 would clear the orientation tab 60.

From FIG. 13, four orientation tabs are shown to allow the housings to sit flat on the orientation tabs when the housings are not properly aligned. The orientation tabs 60 prevent improper assembly of said top housing and said bottom housing members from being installed 90 degrees out of alignment.

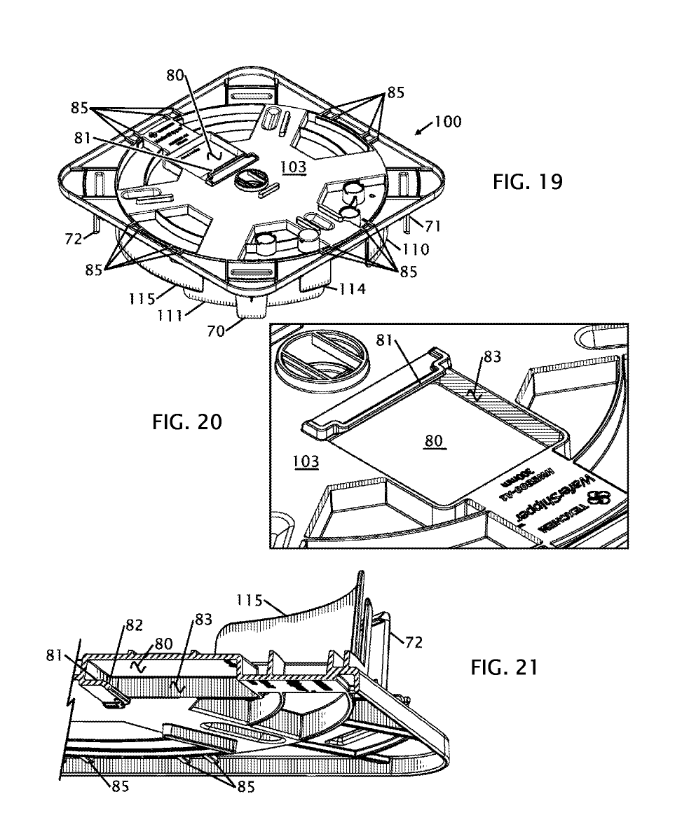

FIG. 19 shows a top perspective view of the bottom housing. FIG. 20 shows a detailed perspective view of the hold down latch. FIG. 21 shows a perspective cross section of the hold down latch. In FIGS. 19 and 21 some parts of the circular ribs 110, 111, 114 and 115 are visible to help to provide a visual orientation for the pocket 80 and latch features. The bottom housing 100 has an undercut hold down recessed pocket 80 with a latch surface tab 81 for a retention mechanism to hold the housing in automated assembly. The latch surface is formed in a molding process with the molding of said bottom housing 100. The latch surface 81 is located at a height that is equal to or lower than the planar bottom surface 103 of said bottom housing 100. The latch surface 81 further has an angled or curved entry surface 82. The pocket further has at least two essentially vertical side walls 83 to self center said bottom housing on said retention mechanism.

The height of the latch is equal to or lower than the inner wall structure to allow equipment to interface with the bottom member of the container without interference with the equipment and recess pocket 80 and the latch surface 81. This recessed feature also protects the mating surface from damage when the top cover is disassembled from the bottom member. In FIGS. 19 and 21 housing latches 70, 71 and 72 are shown. These latches secured the top and bottom housings together.

In FIGS. 19 and 21 a plurality of bearing ribs 85 are shown. These ribs are configured to distribute the load from a bottom housing stacked on top of the top housing. In FIG. 24, it can be seen that the annular lip 87 of the bottom housing 100 is placed at a different dimension from the annular lip 86 of the top housing 50. This allows the housings to stack or nest. When stacking multiple wafer containers together the weight of the container when filled with wafers is significant. Some wafer containers are enclosed in a protective plastic bag, and when the stacked bearing surface is small this creates a high bearing load which damages or punctures the protective bag. Calculation and testing has identified that multiple bearing surfaces 85 of greater than 2.25 mm2 each with more than 4 bearing ribs 85 per quadrant will adequately protect the containers from damage and will also prevent the protective plastic bags from being punctured or damaged.

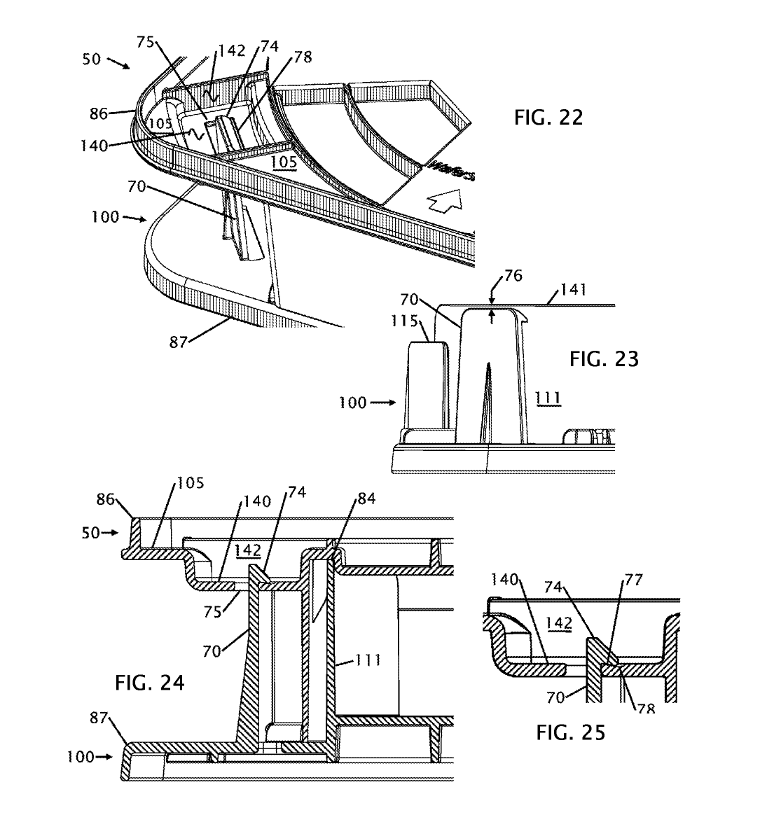

FIG. 22 shows a perspective view of the top and bottom latch tab engaged. FIG. 23 shows a side view of the bottom latch tab. FIG. 24 shows a sectional view of the latch engaged between the top and bottom housings. FIG. 25 shows a detailed view of the engaged between the top and bottom housings. The bottom housing 100 has at least one latch that engages in a corresponding notch 75 located on the top housing 50.

The top surface 74 of said latch 70 is located at a height 76 that is below the top surface of said at least one rib 141. The height 76 of the latch 70 is equal to or lower than the inner wall 141 structure. This allows equipment to interface with the bottom member of the container without interference with the equipment and latch height. This further reduces the possibility of damage to the latch 70 if the bottom housing 100 is dragged on a surface. In the preferred embodiment there are four latches 70 and four corresponding notches 75 located in each corner region of said top housing 50 or said bottom 100 housing, but as few as one or two are contemplate as well as four or more latches. FIG. 25 shows that the notch 70 has a curve entry ramp 77 and a recess 78 that elevates the latch 70 above said entry ramp 77 and lowers said latch 70 into the recess 78 to retain the latch 70 in the recess 78. When the latch(s) are secured the top of the inner rib wall 111 is tightly engaged and captured on the corresponding surface 84 of the top housing 50. The notch 75 is located in a protective latch well 140 that protects the latch 70 during handling and impact. The protective latch well 140 exists below the planar rectangular surface 105 of the top housing 50. The protective latch well is sufficiently sized to limit accidental opening of the latch, and is also sufficiently sized to allows access for human fingers and automated machines that will open the housings. The side walls 142 protective latch well provides only limited clearance between the side walls 142 and the hook 74/notch 75.

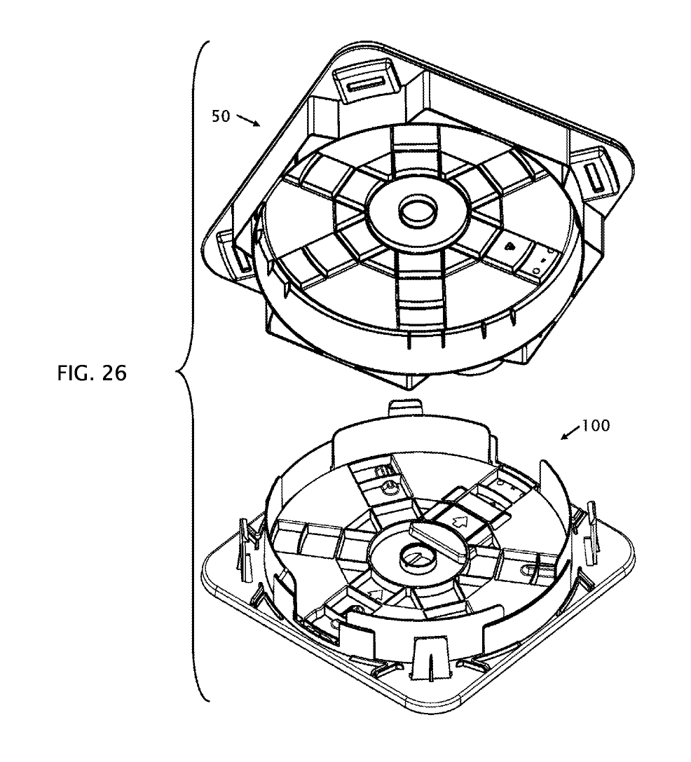

FIG. 26 shows a perspective view of the top and bottom housings in an open exploded view for reference of the internal components. This view provides a view into the open cavity of the top housing 50 and the bottom housing 100 without obstruction of the semiconductor wafers.

Thus, specific embodiments of a semiconductor wafer container have been disclosed. It should be apparent, however, to those skilled in the art that many more modifications besides those described are possible without departing from the inventive concepts herein. The inventive subject matter, therefore, is not to be restricted except in the spirit of the appended claims.

Thus, specific embodiments of a semiconductor wafer container have been disclosed. It should be apparent, however, to those skilled in the art that many more modifications besides those described are possible without departing from the inventive concepts herein. The inventive subject matter, therefore, is not to be restricted except in the spirit of the appended claims.

What is claimed is:

1. A wafer container comprising:
the bottom housing having a base with at least one rib that extends perpendicular from the base of the bottom housing;
the at least one rib on the bottom housing comprising at least one living hinge arranged normal to the base of the bottom housing,
wherein the living hinge is formed from at least one movable wall segment,
wherein the at least one movable wall segment is a flexible panel within the at least one rib on the bottom housing, and
wherein the at least one movable wall segment is unsupported on three sides.

2. The wafer container of claim 1, wherein the at least one rib comprises a plurality of wall segments.

3. The wafer container of claim 1, wherein the plurality of wall segments move radially to maintain the at least one semiconductor wafer concentric with the wafer container.

4. The wafer container of claim 1, wherein the at least one rib comprises at least two movable walls.

5. The wafer container of claim 1, wherein the at least one rib comprises at least four movable walls.

6. The wafer container of claim 1, wherein the at least one rib comprises at least eight movable walls.

7. The wafer container of claim 1, wherein the at least one movable wall has a first closing ramp.

8. The wafer container of claim 7, further comprising a top housing having a base with at least one rib that extends perpendicular from the base of the top housing in an essentially circular orientation.

9. The wafer container of claim 8, wherein the top housing comprises a second closing ramp configured to engage with the first panel closing ramp.

10. The wafer container of claim 9, wherein the bottom housing comprises an inner cavity for storage for at least one semiconductor wafer, and wherein when the second closing ramp engages the first panel closing ramp, at least a portion of the movable wall distal to the living hinge moves towards the inner cavity.

11. A wafer container comprising:
a top housing and a bottom housing;
the bottom housing comprising a base with at least one rib that extends perpendicular from the base of the bottom housing;
the bottom housing having at least one latch that extends essentially perpendicular from the base of the bottom housing, wherein the distance between the base of the bottom housing to the top surface of the latch is less than the distance between the base of the bottom housing and the top of the at least one rib on the bottom housing.

12. The wafer container of claim 11, wherein the top housing comprises at least one latch well comprising a bottom surface and a rim around the well, wherein the bottom surface is located below the surface of a base of the top housing.

13. The wafer container of claim 11, wherein when the top housing is joined with the bottom housing, the top surface of the latch is lower than the rim around the well.

14. The wafer container of claim 11, wherein the latch well comprises a notch configured to receive the at least one latch on the bottom housing.

15. The wafer container of claim 14, wherein the notch has a curved entry ramp.

16. A wafer container comprising:
a bottom housing having a base and an undercut recessed pocket with a latch surface tab, wherein the latch surface tab is parallel to the plane of the base of the bottom housing and partially overlaps the recessed pocket, and wherein the latch surface tab is molded in a molding process with the molding of the bottom housing.

17. The wafer container of claim 16, wherein the pocket further comprises at least two essentially vertical side walls to self-center the bottom housing on the retention mechanism.

18. The wafer container of claim 16, wherein the latch surface is not coplanar with a bottom surface of the base of the bottom housing.

19. The wafer container of claim 16, wherein the latch surface has an angled or a curved entry surface.

20. The wafer container of claim 16, wherein the recessed pocket has a bottom surface, wherein the bottom surface is not coplanar with a bottom surface of the base of the bottom housing.
